(19) United States
(12) Patent Application Publication
(10) Pub. No.: US 2014/0182512 A1
(43) Pub. Date: Jul. 3, 2014

(54) CRYSTAL GROWTH APPARATUS

(71) Applicant: HON HAI PRECISION INDUSTRY CO., LTD., New Taipei (TW)

(72) Inventor: SHAO-HAN CHANG, New Taipei (TW)

(73) Assignee: HON HAI PRECISION INDUSTRY CO., LTD., New Taipei (TW)

(21) Appl. No.: 14/106,863

(22) Filed: Dec. 16, 2013

(30) Foreign Application Priority Data
Dec. 29, 2012 (CN) 2012105892792

(51) Int. Cl. C30B 15/34

(52) U.S. Cl. CPC C30B 15/34
USPC 117/209

(57) ABSTRACT

A crystal growth apparatus includes a first housing, a second housing and a controller received in the second housing. The first housing includes a first main body and defines a growth chamber in the first main body. The second housing includes a second main body and a pulling rod. The second main body defines a transmission chamber and a cooling chamber. The pulling rod is mounted in the transmission chamber, and a first seed rod is mounted on the pulling rod. The controller includes a transmission member and a pair of partition assemblies. The second housing includes a separating sheet and a second seed rod. The separating sheet separates the transmission chamber from the growth chamber. The second seed rod is mounted in the cooling chamber. The pair of partition assemblies move enabling the cooling chamber to communicate with the transmission chamber, such that the transmission member exchanges seed rods.

### BACKGROUND

1. Technical Field

The present disclosure relates to a crystal growth apparatus and particularly to an Edge-defined film-fed crystal growth (EFG) growth apparatus.

2. Description of Related Art

Single crystals such as sapphire have been a material of choice for demanding, high performance optical applications, including various military and commercial applications. Single crystals possess good optical performance, and additionally possess desirable mechanical characteristics, and chemical stability in harsh environments. Methods for manufacturing single crystal sapphire include Kyropoulos method, Czochralski method, heat exchange method, edge-defined film-fed crystal growth (EFG) method and temperature gradient method. The EFG method can directly form single crystal sapphire with desired shape, so the manufacturing process is simple and the utilization rate of materials is improved. A conventional crystal growth apparatus of the EFG method includes a growth chamber and a cooling chamber positioned above the growth chamber and communicates with the growth chamber. The crystal growth apparatus further comprises a pull rod to lift the shaped crystal and pull the crystal to the cooling chamber to be cooled. After that, the crystal is taken out from the cooling chamber. However, this crystal growth apparatus requires a longer cycle time to produce crystals.

Therefore, there is room for improvement in the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views.

FIG. 1 is a cross-sectional view of a crystal growth apparatus in a first embodiment of this disclosure.

FIG. 2 is a cross-sectional view of the crystal growth apparatus of FIG. 1 in a crystal growing process.

FIG. 3 is a cross-sectional view of the crystal growth apparatus of FIG. 1 in a crystal transmitting process.

FIG. 4 is a cross-sectional view of a crystal growth apparatus in a second embodiment of this disclosure.

### DETAILED DESCRIPTION

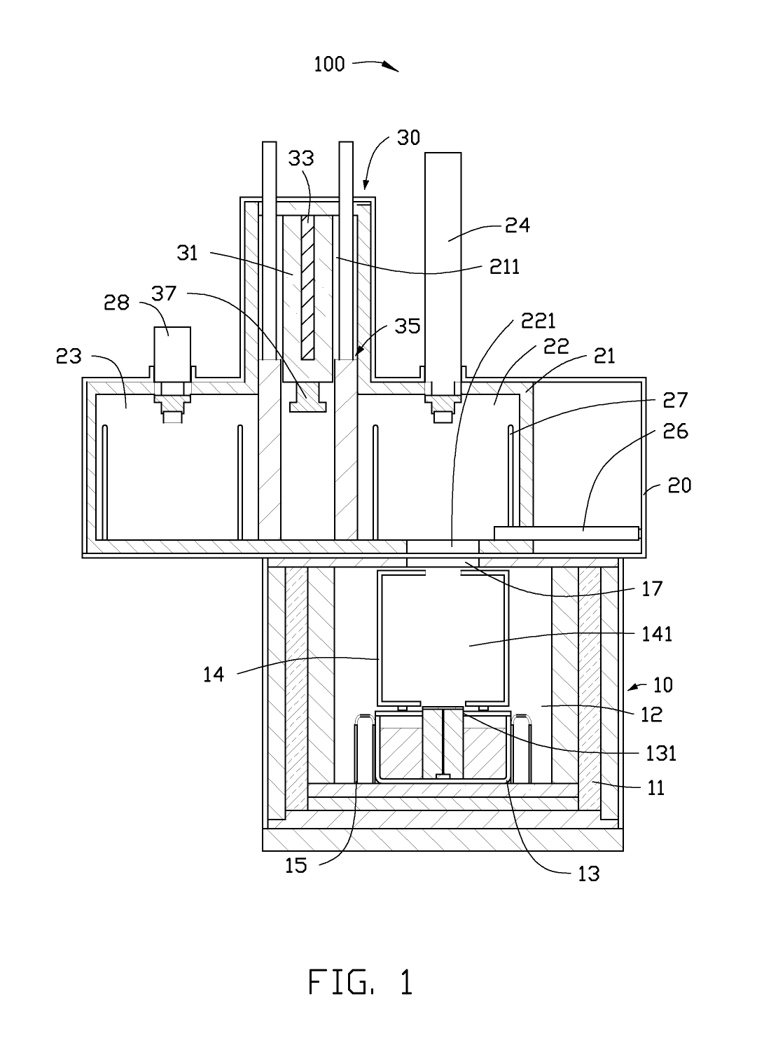

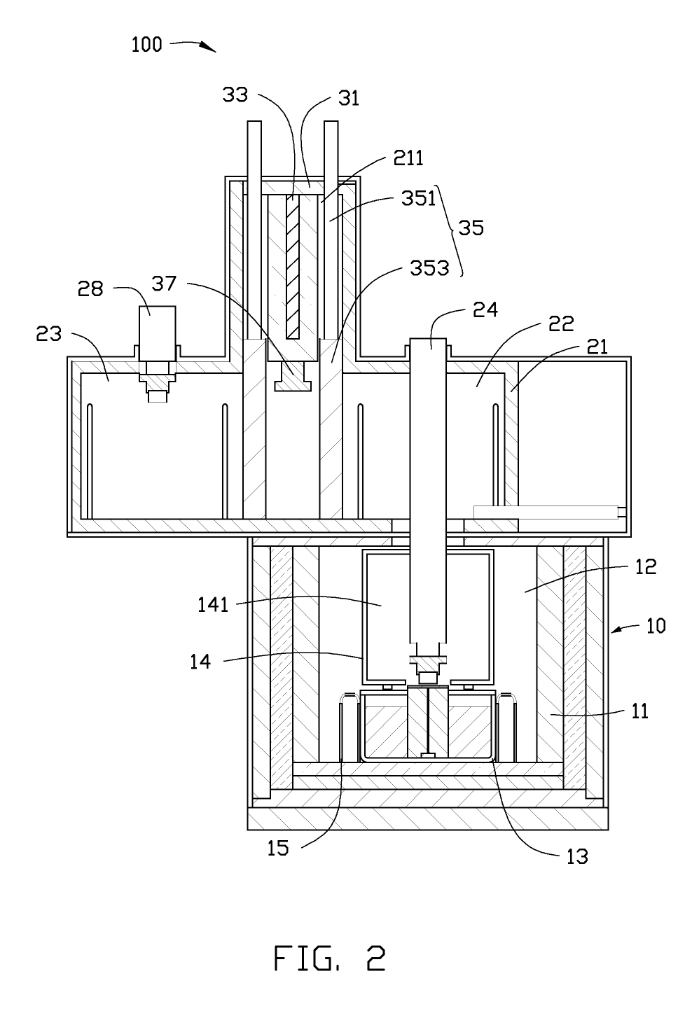

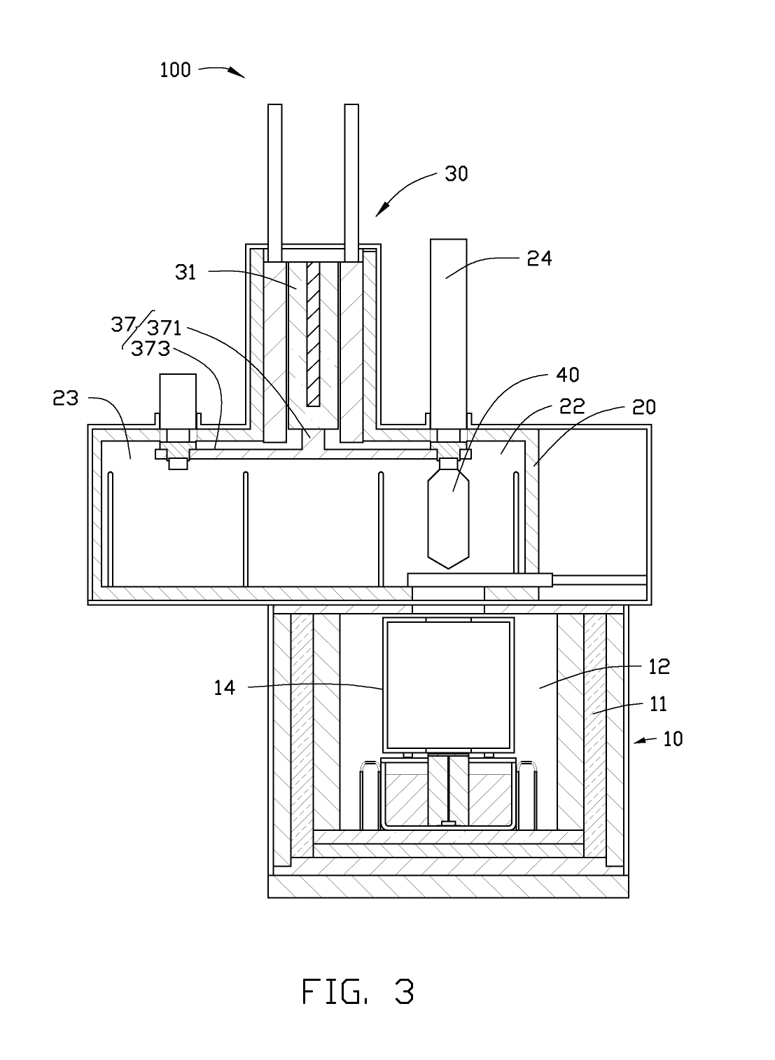

FIG. 1 and FIG. 2 show a crystal growth apparatus 100 in a first embodiment of this disclosure. The crystal growth apparatus 100 is configured for producing crystals 40 (see FIG. 3) by EFG method. The crystal growth apparatus 100 includes a first housing 10, a second housing 20 positioned above the first housing 10, and a controller 30 received in the second housing 20. The first housing 10 includes a first main body 11 and defines a growth chamber 12 in the first main body 11. The second housing 20 includes a second main body 21, and defines a transmission chamber 22 and a cooling chamber 23 that are parallel to each other in the second main body 21. The controller 30 is mounted in the second main body 21 and separates the transmission chamber 22 and the cooling chamber 23. The transmission chamber 22 is arranged above the growth chamber 12, and the cooling chamber 23 is arranged on one side of the transmission chamber 22. The transmission chamber 22 is configured for temporarily receiving the crystal 40 shaped in the growth chamber 12. The controller 30 is capable of withdrawing to enable the cooling chamber 23 to communicate with the transmission chamber 22, and transmitting the crystal 40 from the transmission chamber 22 to the cooling chamber 23 to be cooled. In this embodiment, the crystal growth apparatus 100 is configured for producing single crystal sapphires. The crystal growth apparatus 100 can also produce other crystals, such as scintillating crystals, and single silicon crystals.

The first housing 10 further includes a receiving portion 13, a heat insulator 14 and a heater 15. The first main body 11 is made of a plurality of insulating layers coated to a cube. The growth chamber 12 is positioned in the first main body 11. The main first body 11 includes a transfer port 17 at an end adjacent to the second housing 20. The receiving portion 13, the heat insulator 14 and the heater 15 are received in the growth chamber 12. The receiving portion 13 is configured for receiving raw materials of the shaped crystal sapphire (α-Al₂O₃ in molten state), and includes an opening 131. The heat insulator 14 is mounted on the receiving portion 13, and includes a molding cavity 141 with openings at both ends. One end of the molding cavity 141 communicates with the opening 131, and the other end of the molding cavity 141 communicates with the transfer port 17. The heater 15 that surrounds the receiving portion 13 is configured for heating the receiving portion 13.

The second housing 20 further includes a pulling rod 24, a separating sheet 26, a plurality of heating members 27 and a supporting rod 28 received in the second main body 21. The second main body 21 is made of a number of insulating layers coated to a box shape. The second main body 21 protrudes from one side and between the transmission chamber 22 and the cooling chamber 23 to form a housing portion 211 configured for accommodating the controller 30. The bottom wall of the transmission chamber 22 defines a communication port 221 communicating with the transfer port 17 and the molding cavity 141. The pulling rod 24 is slidably arranged on one side of the transmission chamber 22 away from the first main body 11, and in the direct line with the communication port 221 and the transfer port 17. The pulling rod 24 is capable of passing through the communication port 221, the transfer port 17 and the molding cavity 141 to insert into the receiving portion 13. A first seed rod (not figured) is detachably mounted on the pulling rod 24 to pull the shaped crystals. The separating sheet 26 is movably arranged on one side of the communication port 221. When the pulling rod 24 lifts the crystals to the transmission chamber 22, the separating sheet 26 blocks the communication port 221 to separate the transmission chamber 22 and the molding cavity 141. The heating members 27 are positioned in the transmission chamber 22 and the cooling chamber 23. The supporting rod 28 is mounted on the top of the cooling chamber 23. The supporting rod 28 includes a second seed rod (not figured) to exchange with the seed rod on the crystal 40, thus the crystal 40 is transmitted. The second seed rod is detachably mounted on the supporting rod 28.

The controller 30 is mounted in the housing portion 211, including an insulating base 31, a heating body 33, a pair of partition assemblies 35 and a transmission member 37. The insulating base 31 is positioned in the housing portion 211, and the heating body 33 is positioned in the insulating base 31, configured for heating the insulating base 31 and the partition assemblies 35. The two partition assemblies 35 are movably arranged on the two ends of the insulating base 31 and extend between the transmission chamber 22 and the cooling chamber 23, so as to separate the transmission chamber 22 and the cooling chamber 23. The partition assembly 35 includes a connection member 351 and a partition member 353. The connection member 351 is movably mounted on the insulating base 31, and the partition member 353 is fixed to the connection member 351. The connection member 351 is capable of moving upward to enable the cooling chamber 23 to communicate with the transmission chamber 22. In this embodiment, the partition member 353 is plate shape. The transmission member 37 is rotatable and arranged between the two partition assemblies 35. FIG. 3 shows the crystal growth apparatus 100 in a crystal transmitting process. The transmission member 37 includes a rotary part 371 and a transfer part 373, and the central of the transfer part 373 is fixed to the rotary part 371. The rotary part 371 is rotatable and arranged on the insulating base 31. The transfer part 373 is long strip shaped, and the two ends of the transfer part 373 are used to grasp the feed rods.

In assemble, first, the receiving portion 13 is positioned in the growth chamber 12, the heat insulator 14 is mounted above the receiving portion 13, and the opening 131 is communicated with the transfer port 17. The heater 15 is positioned around the receiving portion 13. Then, the pulling rod 24 is movably arranged on the transmission chamber 22 above the communication port 221, and a first feed rod is mounted on the pulling rod 24. The separating sheet 26 is movably arranged above the communication port 221. A plurality of heating members 27 are positioned in the transmission chamber 22 and the cooling chamber. The supporting rod 28 is mounted above the cooling chamber 23, and a second feed rod is mounted on the support rod 28. After that, the insulating base 31 is positioned between the transmission chamber 22 and the cooling chamber 23, and the heating body 33 is positioned in the insulating base 31. The two partition assemblies 35 are movably positioned at the two ends of the insulating base 31, configured for closing the transmission chamber 22 and the cooling chamber 23. The transmission member 37 is positioned between the two partition assemblies 35.

In use, the raw material of the sapphire in the receiving portion 13 are heated to a molten state by the heater 15. A seed is mounted on the first seed rod of the pulling rod 24, and the pulling rod 24 passes through the communication port 221, the transfer port 17 and the molding cavity 141 to insert into the receiving portion 13, so as to grow crystal. The cooling chamber 23 is evacuated and then charged with protect gas (such as argon gas). The cooling chamber 23 is heated by the heating member 27, and the temperature of the second seed rod on the supporting rod 28 is raised. After the crystal growing process is completed, the crystal 40 is lifted to the transmission chamber 22 by the pulling rod 24, and the communication port 221 is blocked by the separating sheet 26 to separate the partition assembly 35 and the transmission member 37. The temperature of the crystal 40 is descend in the transmission chamber 22. The heating body 33 is stated to heat the partition assemblies 35 and the transmission member 37. When the crystal 40, the second feed rod in the cooling chamber 23, the partition assemblies 35 and the transmission member 37 have the similar temperature (for example: 1350° C.), the connecting members 351 move upward with the partition members 353 relative to the insulating base 31 to communicate the transmission chamber 22 with the cooling chamber 23. The rotary part 371 rotates 90 degrees with the transfer part 373. Thereby the two ends of the transfer part 373 are positioned near the support rod 28 and the pulling rod 24. One end of the transfer part 373 grasps the first seed rod on the pull rod 24, and the rotary part 371 rotates 180 degrees, thus the first seed rod and the crystal on the first seed rod are transmitted to the support rod 28. At the same time, the second seed rod on the support rod 28 are transmitted to the pulling rod 24. The transmission member 37 rotates 90 degrees again to be parallel with the partition assemblies 35. The partition assemblies 35 separate the transmission chamber 22 and the cooling chamber 23. The heating members 27 in the cooling chamber 23 and the heating body stop heating to cool the crystal 40 and the controller 30. The heating members 27 start to heat in the transmission chamber 22, then a separating sheet 26 moves to expose the communication port 221, and the pulling rod 24 inserts into the growth chamber 12 to grow crystal again. When the cooling chamber is cooled to room temperature, the cooling chamber 23 is opened to pull out the crystal, and then a seed is mounted. The crystal growth process is repeated.

The controller 30 is positioned between the transmission chamber 22 and the cooling chamber 23, so the pulling rod 24 is inserted into the growth chamber 12 for growing crystals when the crystal 40 is cooled in the cooling chamber. Therefore, the cycle time of producing the single sapphire crystal is reduced.

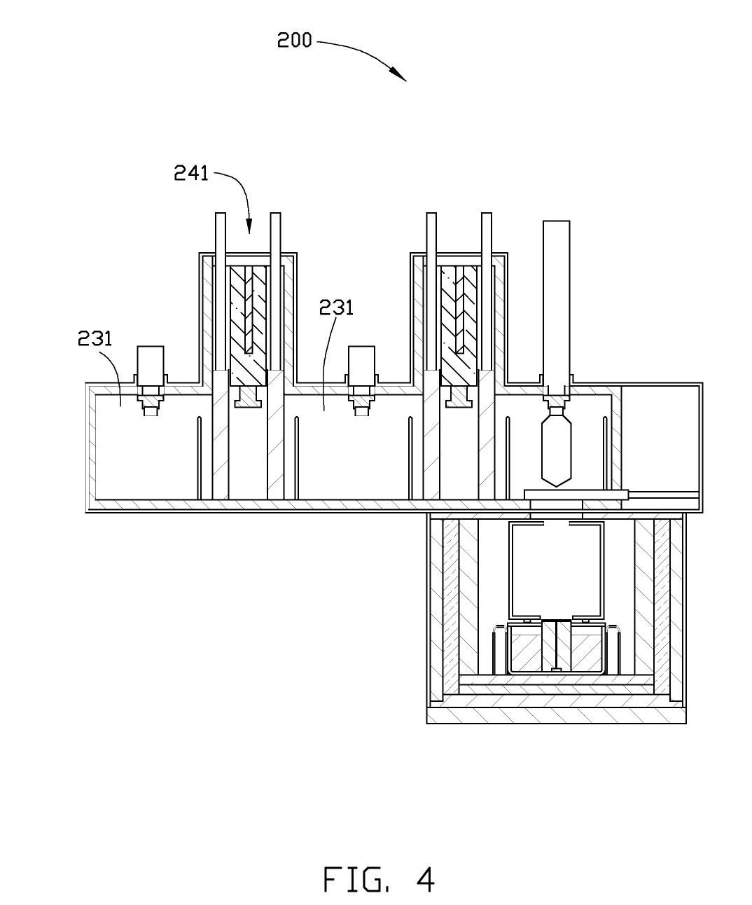

FIG. 4 shows a crystal growth apparatus 200 in a second embodiment of this disclosure. The crystal growth apparatus 200 includes two cooling chambers 231 parallel to each other and a controller 241 positioned between the two cooling chambers 231. The crystal 40 is cooled gradually by the two cooling chambers 231 in the crystal growth apparatus 200, so the production efficiency is improved.

The crystal growth apparatus may include a plurality of cooling chambers 23, and a plurality of corresponding controllers 30. The transmission chamber 22 communicates with the cooling chamber 23 at one end. The controllers 30 are positioned between the transmission chamber 22 and the cooling chamber 23, and between the plurality of controllers 30.

The crystal growth apparatus may have only one partition assembly 35, and the transmission member 37 is positioned at one side of the transmission chamber 22 or the cooling chamber 23.

The transmission member 37 may be a flexible gripper claw. When the transmission chamber 22 is communicated with the cooling chamber 23, the flexible gripper claw is enable to extend to the pulling rod 24 to grasp the seed rod, and then extend to the supporting rod 28 with the crystal 40.

It is believed that the present embodiments and their advantages will be understood from the foregoing description, and it will be apparent that various changes may be made thereto without departing from the spirit and scope of the embodiments or sacrificing all of its material advantages.

What is claimed is:

1. A crystal growth apparatus, comprising:
a first housing comprising a first main body and defining a growth chamber in the first main body; and
a second housing arranged above the first housing, the second housing comprising a second main body and a pulling rod, and defining a cooling chamber in the second main body;
wherein the second main body includes a transmission chamber communicated with the cooling chamber; the pulling rod is slidably mounted in the transmission chamber, and a first seed rod is detachably mounted on the pulling rod; the crystal growth apparatus further comprises a controller positioned in the second main body; the controller comprises a transmission member and at least one partition assembly, and the partition assembly separates the transmission chamber and the cooling chamber; the second main body further comprises a separate sheet and a second seed rod detachably mounted in the cooling chamber; the separate sheet is movably in the transmission chamber to separate the transmission chamber from the growth chamber; and the partition assemblies are capable of moving to enable the cooling chamber to communicate with the transmission chamber, such that the transmission member exchanges the first seed rod and the second seed rod.

2. The crystal growth apparatus of claim 1, wherein the second body protrudes from one side and between the transmission chamber and the cooling chamber to form a housing portion, and the controller is positioned in the housing portion; the controller comprises two partition assemblies, and the transmission member is rotatable and positioned between the two partition assemblies.

3. The crystal growth apparatus of claim 2, wherein the controller further comprises an insulating base and a heating body; the insulating base is positioned in the housing portion, the heating body is positioned in the insulating base, and the two partition assemblies are positioned on the two sides of the insulating base.

4. The crystal growth apparatus of claim 3, wherein the partition assembly comprises a connection member and a partition member; the connection member is movably mounted on the insulating base, and the partition member is fixed on the connection member.

5. The crystal growth apparatus of claim 3, wherein the transmission member comprises a rotary part and a transfer part, and the central part of the transfer part is fixed on the rotary part; the rotary part is capable of driving the transfer part to rotate, and the two ends of the transfer part are positioned in the transmission chamber and the cooling chamber.

6. The crystal growth apparatus of claim 5, wherein the second housing further comprises a plurality of heating members and a supporting rod mounted on the cooling chamber; the heating members are positioned in the transmission chamber and the cooling chamber; a second seed rod is detachably mounted on the pulling rod; and the transfer member is capable of exchanging the first seed rod on the pulling rod with the second seed rod.

7. The crystal growth apparatus of in claim 1, wherein the first housing further comprises a receiving portion and a heat insulator positioned in the growth chamber, the receiving portion is configured for receiving a melted liquid of raw materials of the crystal and defining an opening; the heat insulator is mounted on the receiving portion, and defines a molding cavity communicates with one end of the opening.

8. The crystal growth apparatus of claim 1, wherein the transmission chamber and the cooling chamber are arranged parallel to each other in the second main body; the transmission chamber is arranged above the growth chamber, and the cooling chamber is arranged on one side of the transmission chamber.

9. The crystal growth apparatus of claim 1, wherein the second main body defines a communication port at the bottom wall of the transmission chamber; the first main body defines a transfer port; the transmission port communicates with the communication port; the pulling rod, the transfer port and the communication port are in a direct line.

10. A crystal growth apparatus, comprising:
a first housing comprising a first main body and defining a growth chamber in the first main body; and
a second housing arranged above the first housing, and the second housing comprising a second main body and a pulling rod;
wherein the second main body includes a plurality of cooling chambers arranged parallel to each other in the second main body, and a transmission chamber communicates with the growth chamber; the transmission chamber communicates with a cooling chamber at one end; crystal growth apparatus further comprises a plurality of controllers positioned between the transmission chamber and the cooling chamber at the end, and between two cooling chambers; the controller comprises a transmission member and a partition assembly; the pulling rod is slidably mounted in the transmission chamber, and a first seed rod is detachably mounted on the pulling rod; the transfer member is ratably positioned in the second main body, the partition assemblies separates the transmission chamber and the cooling chamber at the end, and the cooling chambers; the second main body further comprises a separate sheet and a second seed rod detachably mounted in the cooling chamber; the separate sheet is movably in the transmission chamber to separate the transmission chamber from the growth chamber; the partition assemblies are capable of moving to enable the cooling chamber to communicate with the transmission chamber, such that the transmission member exchanges the first seed rod and the second seed rod in the cooling chamber at the end, and transfers the first seed rod from a cooling chamber to a neighbored cooling chamber in the transmission chamber.
